(19) United States
(12) Patent Application Publication
(10) Pub. No.: US 2005/0059780 A1
(43) Pub. Date: Mar. 17, 2005

(54) Diaphragm, particularly in laminators for the production of photovoltaic cells

(75) Inventors: Joachim Bormuth, Biblis (DE); Manfred Glatter, Wangen (DE); Anton Klesen, Tholey (DE)

Correspondence Address: Stephen B. Salai, Esq.;Harter, Secrest & Emery LLP, 1600 Bausch & Lomb Place, Rochester, NY, 14604-2711, US

(73) Assignee: Metzeler Technical Rubber Systems GmbH, Mannheim (DE)

(21) Appl. No.: 10/821,002

(22) Filed: Apr. 8, 2004

(30) Foreign Application Priority Data
Apr. 11, 2003 (DE) 103 16 774.9

(51) Int. Cl. C08L 27/12

(52) U.S. Cl. 525/199

(57) ABSTRACT

A diaphragm in laminators for the production of photovoltaic cells, including a flexible body comprising at least one first layer engineered as an elastomeric conformable composite of fluorinated rubber or fluorinated silicone rubber and a first cross-linkable polymeric material, the proportion of fluorinated rubber or fluorinated silicone rubber being in the range of 95.0% by weight to 1.0% by weight, and said first cross-linkable polymeric material being selected from the group comprising hydrated nitrile rubber, ethylene propylene diene rubber, acrylic nitrile butadiene rubber, ethylene vinyl acetate rubber, fluorinated silicone rubber, silicone rubber or a blend of at least two of these materials.

### CROSS-REFERENCE TO RELATED APPLICATIONS

Not applicable.

### STATEMENT REGARDING FEDERALLY SPONSORED RESEARCH OR DEVELOPMENT

Not Applicable.

### REFERENCE TO A “SEQUENCE LISTING”

Not applicable.

### BACKGROUND OF THE INVENTION

1. Field of the Invention

The invention relates to a diaphragm for application particularly in laminators for the production of photovoltaic cells and including a flexible body. The invention relates furthermore to a laminator in which such a diaphragm is employed.

2. Description of Related Art

In the production of photovoltaic cells, for example a solar module, laminators are employed which serve to join the various layers of the solar module together.

Known laminators such as described, for example, in U.S. Pat. No. 6,149,757, comprise a working chamber defined by a diaphragm. The diaphragm has a dual function. For one thing, it serves to close off the working chamber air-tight. For another, the diaphragm exerts a predefined contact pressure on the layers of the solar module to be joined together. This pressing action usually takes place at an elevated temperature.

Accordingly, the requirements placed on the physical properties of the diaphragm involve an extremely low gas permeability, high heat resistance and high conformability. To satisfy these requirements, conventional diaphragms are usually made of silicone rubber featuring a high heat resistance up to temperatures of approximately 200° C. and elastomeric conformability.

The disadvantage discovered with such silicone diaphragms is that they tend to become brittle and thus useless in a relatively short time.

### BRIEF SUMMARY OF THE INVENTION

The invention has the object of sophisticating a diaphragm of the aforementioned kind so that it achieves a relatively long useful life.

To achieve this object with a diaphragm comprising a flexible body it is provided for in accordance with the invention that the body comprises at least one first layer engineered as an elastomeric conformable composite of fluorinated rubber (FKM) or fluorinated silicone rubber (FVMQ) and a first cross-linkable polymeric material. The proportion of fluorinated rubber or fluorinated silicone rubber is in the range of 95.0% by weight to 1.0% by weight, and said first cross-linkable polymeric material being selected from the group comprising hydrated nitrile rubber, ethylene propylene diene rubber, acrylic nitrile butadiene rubber, ethylene vinyl acetate rubber, fluorinated silicone rubber, silicone rubber or a blend of at least two of these materials.

A diaphragm engineered as such has sufficient gas impermeability whilst featuring a high heat resistance and conformability. In addition, the diaphragm in accordance with the invention features a relatively high resistance to the chemical products released in lamination in counteracting embrittlement of the diaphragm and thus resulting in a significant longer life of the diaphragm in accordance with the invention as compared to conventional silicone diaphragms.

Advantage aspects of the diaphragm in accordance with the invention read from the claims 3 to 10.

It has been discovered to be particularly advantageous when the first cross-linkable polymeric material is hydrated nitrile rubber (HNBR), ethylene propylene diene rubber (EPDM), ethylene vinyl acetate rubber (EVA), fluorinated silicone rubber (FVMQ), silicone rubber (VMQ) or a blend of at least two of these materials.

It is furthermore of advantage when the second cross-linkable polymeric material is hydrated nitrile rubber (HNBR), ethylene propylene diene rubber (EPDM), acrylic nitrile butadiene rubber (NBR), ethylene vinyl acetate rubber (EVA), fluorinated rubber (FKM), silicone rubber (VMQ) or a blend of at least two of these materials.

In one preferred aspect of the diaphragm in accordance with the invention the body comprises a second layer engineered from the first cross-linkable polymeric material, and/or the second cross-linkable polymeric material. The second layer may be made, for example, solely of silicone rubber to thus ensure relatively cost-effective production.

Advantageously, the first layer is a cover layer preferably 0.5 mm to 1.0 mm thick and the second layer is a base layer preferably 1.5 mm to 3.5 mm thick. The cover layer, thinner as a rule as compared to the base layer, mainly serves to protect the diaphragm, whereas the base layer contributes towards adequate gas impermeability, heat resistance and conformability of the diaphragm.

In another preferred aspect of the diaphragm in accordance with the invention the first layer comprises a proportion of fluorinated rubber (FKM) in the range of 90.0% by weight and 5.0% by weight or a proportion of fluorinated silicone rubber (FVMQ) in the range of 90.0% by weight and 5.0% by weight.

In yet another preferred aspect of the diaphragm in accordance with the invention the second layer comprises a proportion of silicone rubber (VMQ) in the range of 100.0% by weight to 0.0% by weight, preferably in the range of 90.0% by weight and 10.0% by weight or a proportion of fluorinated silicone rubber (FVMQ) in the range of 100.0% by weight and 0.0% by weight, preferably in the range of 90.0% by weight and 10.0% by weight, or a proportion of fluorinated rubber (FKM) in the range of 100.0% by weight and 0.0% by weight, preferably in the range of 90.0% by weight and 10.0% by weight. The second layer may accordingly be engineered, for example, solely in VMQ or a blend of VMQ with one or more polymeric materials.

In conclusion, as it reads from claims 11 and 12 a laminator is proposed, serving more particularly for laminating photovoltaic cells and featuring a diaphragm in accordance with the invention. For use in a laminator it is expedient to arrange a dual-layer diaphragm such that the cover layer faces the products dissociating from the EVA film used in the production of the solar module.

### BRIEF DESCRIPTION OF THE SEVERAL VIEWS OF THE DRAWING(S)

Further advantages of the diaphragm in accordance with the invention will now be detailed in the description of two preferred embodiments illustrated in the drawings merely diagrammatically in which:

FIG. 1 is a diagrammatic illustration of a single-layer diaphragm and

FIG. 2 is a diagrammatic illustration of a dual-layer diaphragm.

### DETAILED DESCRIPTION OF THE INVENTION

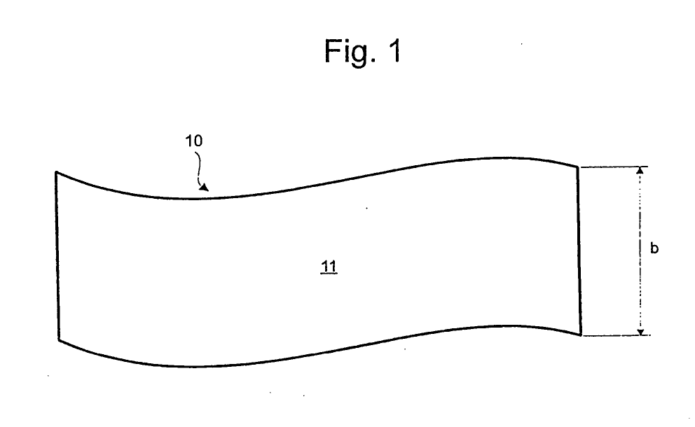

Referring now to FIG. 1 there is illustrated how the diaphragm comprises a sheet body 10 consisting of a layer 11. The body 10 accordingly featuring a single-layer configuration has a thickness b of approximately 3.5 mm and is engineered as an elastomeric material which may be a composite of FKM and a cross-linkable polymeric material such as for example HNBR, EDPD, NBR, EVA, FVMQ, VMQ and blends of the aforementioned polymeric materials or a composite of FVMQ and a cross-linkable polymeric material such as, for example, HNBR, EDPD, NBR, EVA, FKM, VMQ or blends of the aforementioned polymeric materials. The choice of material depends on the intended application, the same applying to the ratio of the proportions of individual components in the composite material. Common however to the requirements of all of the aforementioned materials is that they exhibit adequate gas impermeability and feature a relatively high heat resistance and conformability. In addition the materials are relatively resistant to the products of chemical dissociation such as, for example, the products dissociating on heating the EVA. The diaphragm is thus particularly suitable for use in a laminator, by means of which photovoltaic cells, for example solar modules, are produced in using a film of EVA.

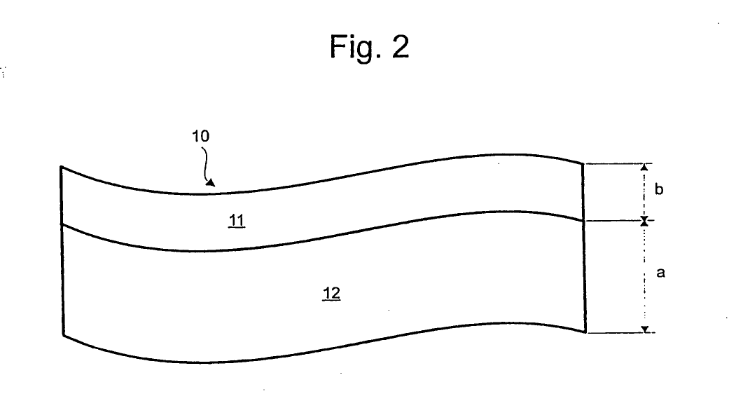

Referring now to FIG. 2 there is illustrated how the diaphragm comprises a sheet body 10 having a dual-layer configuration, the body 10 consisting of a base layer 12 and a cover layer 11. The base layer 12 has a thickness approximately 3.0 mm, whereas the thickness b of the cover layer 11 is approximately 0.5 mm. Both the base layer 12 and the cover layer 11 are engineered as an elastomeric conformable material sufficiently gas impermeable and featuring a relatively high heat resistance for temperatures up to approximately 200° C. The cover layer 11 may be made of the same material as the diaphragm as shown in FIG. 1. The cover layer 11 thus endows the diaphragm with a relatively high resistance to the chemical products disassociating in laminating photovoltaic cells. By contrast, the base layer 12 may be engineered solely in VMQ as is usual in conventional silicone diaphragms to ensure simple, cost-effective production. As an alternative, the base layer 12 may also be engineered from FVMQ, FKM or in blends of, for example, VMQ and FVMQ or FKM and FVMQ to satisfy the special requirements of the particular application.

The embodiments of a diaphragm as described above excel by a relatively long life, the reason for this being how the diaphragm is engineered in ensuring a relatively high resistance to the chemical products dissociated in both the single-layer and dual-layer version. The inherent elastomeric response of the diaphragm is thus retained for a lengthy period of time without the risk of embrittlement.

1. A diaphragm in laminators for the production of photovoltaic cells, including a flexible body comprising at least one first layer engineered as an elastomeric conformable composite of fluorinated rubber and a first cross-linkable polymeric material, the proportion of fluorinated rubber being in the range of 95.0% by weight to 1.0% by weight, and said first cross-linkable polymeric material being selected from the group comprising hydrated nitrile rubber, ethylene propylene diene rubber, acrylic nitrile butadiene rubber, ethylene vinyl acetate rubber, fluorinated silicone rubber, silicone rubber or a blend of at least two of these materials.

2. A diaphragm in laminators for the production of photovoltaic cells, including a flexible body comprising at least one first layer engineered as an elastomeric composite of fluorinated silicone rubber and a second cross-linkable polymeric material, the proportion of fluorinated silicone rubber being in the range of 95.0% by weight to 1.0% by weight, said second cross-linkable polymeric material being selected from the group comprising hydrated nitrile rubber, ethylene propylene diene rubber, acrylic nitrile butadiene rubber, ethylene vinyl acetate rubber, fluorinated rubber, silicone rubber or a blend of at least two of these materials.

3. The diaphragm as set forth in claim 1, wherein said body comprises a second layer engineered from said first cross-linkable polymeric material or said second cross-linkable polymeric material.

4. The diaphragm as set forth in claim 2, wherein said body comprises a second layer engineered from said first cross-linkable polymeric material or said second cross-linkable polymeric material.

5. The diaphragm as set forth in claim 3, wherein said first layer is a cover layer preferably 0.5 mm to 1.0 mm thick and said second layer is a base layer preferably 1.5 mm to 3.5 mm thick.

6. The diaphragm as set forth in claim 4, wherein said first layer is a cover layer preferably 0.5 mm to 1.0 mm thick and said second layer is a base layer preferably 1.5 mm to 3.5 mm thick.

7. The diaphragm as set forth in claim 1, wherein said first layer comprises a proportion of fluorinated rubber in the range of 90.0% by weight to 5.0% by weight, or a proportion of fluorinated silicone rubber in the range of 90.0% by weight to 5.0% by weight.

8. The diaphragm as set forth in claim 2, wherein said first layer comprises a proportion of fluorinated rubber in the range of 90.0% by weight to 5.0% by weight, or a proportion of fluorinated silicone rubber in the range of 90.0% by weight to 5.0% by weight

9. The diaphragm as set forth in claim 3, wherein said second layer comprises a proportion of silicone rubber in the range of 100.0% by weight to 0.0% by weight, preferably in the range of 90.0% by weight and 10.0% by weight, or a proportion of fluorinated silicone rubber in the range of 100.0% by weight and 0.0% by weight, preferably in the range of 90.0% by weight and 10.0% by weight, or a proportion of fluorinated rubber in the range of 100.0% by weight and 0.0% by weight, preferably in the range of 90.0% by weight and 10.0% by weight.

10. The diaphragm as set forth in claim 4, wherein said second layer comprises a proportion of silicone rubber in the range of 100.0% by weight to 0.0% by weight, preferably in the range of 90.0% by weight and 10.0% by weight, or a proportion of fluorinated silicone rubber in the range of 100.0% by weight and 0.0% by weight, preferably in the range of 90.0% by weight and 10.0% by weight, or a proportion of fluorinated rubber in the range of 100.0% by weight and 0.0% by weight, preferably in the range of 90.0% by weight and 10.0% by weight.

11. A laminator for the production of photovoltaic cells, having a diaphragm as set forth in claim 1.

12. A laminator for the production of photovoltaic cells, having a diaphragm as set forth in claim 2.
